(19) United States
(12) Patent Application Publication
(10) Pub. No.: US 2015/0184297 A1
(43) Pub. Date: Jul. 2, 2015

(54) METHOD FOR FORMING TUNGSTEN SULFIDE LAYER AND APPARATUS FOR FORMING TUNGSTEN SULFIDE LAYER

(71) Applicant: Industry-Academic Cooperation Foundation, Yonsei University, Seoul (KR)

(72) Inventors: Hyungjun KIM, Seoul (KR); Won Seon LEE, Incheon (KR); Jusang Park, Seoul (KR)

(21) Appl. No.: 14/588,769

(22) Filed: Jan. 2, 2015

(30) Foreign Application Priority Data
Jan. 2, 2014 (KR) 10-2014-0000317

(51) Int. Cl. C23C 16/455; C23C 16/46; C01G 41/00

(52) U.S. Cl. CPC C23C 16/45544; C01G 41/00; C23C 16/45525; C23C 16/46

(57) ABSTRACT

Provided are an apparatus and method for forming a tungsten sulfide layer. The method for forming a tungsten sulfide layer by using atomic layer deposition includes reacting a precursor including a gaseous tungsten chloride and a reactant including hydrogen sulfide to form a tungsten sulfide layer on a substrate.

### CROSS-REFERENCE TO RELATED APPLICATIONS

This U.S. non-provisional patent application claims priority under 35 U.S.C. §119 of Korean Patent Application No. 10-2014-0000317, filed on Jan. 2, 2014, the entire contents of which are hereby incorporated by reference.

### BACKGROUND OF THE INVENTION

The present invention disclosed herein relates to a method for forming a tungsten sulfide layer and an apparatus for forming a tungsten sulfide layer, and more particularly, to a method for forming a tungsten sulfide layer on a substrate by using atomic layer deposition and an apparatus for forming a tungsten sulfide layer by using the same.

Tungsten sulfide (WS₂) is a material having high electron mobility and flexible characteristics. Thus, tungsten sulfide (WS₂) may be suitable for being used as a channel layer for realizing flexible thin film transistors, flexible displays, and the like. A chemical vapor deposition (CVD) method has been used as the typical method for synthesizing tungsten sulfide (WS₂). In case of the CVD method, it may be difficult to adjust a thickness of tungsten sulfide (WS₂) to a nano level, and there is a limitation that it is difficult to uniformly grow tungsten sulfide (WS₂) having a two-dimensional nano-structure on a large area. As described above, since it is difficult to uniformly grow tungsten sulfide (WS₂) over the large area through the typical CVD method, electrical and optical properties vary according to a variation in thickness of the tungsten sulfide layer.

### SUMMARY OF THE INVENTION

The present invention provides an apparatus and method for forming a tungsten sulfide layer, which are capable of uniformly forming the tungsten sulfide layer over a large area.

Technical objects to be solved by the present invention are not limited to the aforementioned technical objects and unmentioned technical objects will be clearly understood by those skilled in the art from the specification and the appended claims.

Embodiments of the present invention provide methods for forming a tungsten sulfide layer by atomic layer deposition, the methods including: reacting a precursor including a gaseous tungsten chloride and a reactant including hydrogen sulfide to form a tungsten sulfide layer on a substrate.

In some embodiments, the methods may further include heating a tungsten chloride of solid state to generate the precursor comprising the gaseous tungsten chloride.

In other embodiments, the heating the tungsten chloride of solid state may include heating the tungsten chloride of solid state at a temperature of about 60° C. to about 100° C. to generate the gaseous tungsten chloride.

In still other embodiments, the tungsten sulfide layer may include at least one tungsten sulfide molecular layer, each of the at least one tungsten sulfide molecular layer has a thickness deviation of about 0 nm to about 0.3 nm.

In even other embodiments, the forming the tungsten sulfide layer may further include: supplying the precursor including the gaseous tungsten chloride onto the substrate in a chamber; and supplying the reactant including the hydrogen sulfide onto the substrate, wherein the supplying the precursor and the supplying the reactant are repeatedly performed to form the tungsten sulfide layer including at least one tungsten sulfide molecular layer on the substrate.

In yet other embodiments, the supplying the precursor may include supplying the gaseous tungsten chloride into the chamber so that the tungsten chloride within the chamber has a partial pressure of about 0.01 torr to about 0.02 torr.

In further embodiments, each of the at least one tungsten sulfide molecular layer has a thickness deviation of about 0 nm to about 0.3 nm.

In still further embodiments, the supplying the precursor may include bubbling an inert gas to introduce the gaseous tungsten chloride into the chamber.

In even further embodiments, the inert gas may include at least one selected from an argon gas and a nitrogen gas, and the bubbling the inert gas may include bubbling the inert gas so that the inert gas within the chamber has a flow rate of about 10 sccm to about 20 sccm.

In yet further embodiments, the supplying the reactant may include supplying the hydrogen sulfide into the chamber so that the hydrogen sulfide within the chamber has a partial pressure of about 0.05 torr to about 0.15 torr.

In other embodiments of the present invention, apparatuses for forming a tungsten sulfide layer by atomic layer deposition include: a chamber; a precursor supply unit for supplying a precursor including tungsten chloride into the chamber, the precursor supply unit includes a heating device for heating tungsten chloride of a solid state to generate the gaseous tungsten chloride; and a reactant supply unit for supplying a reactant including hydrogen sulfide into the chamber.

In some embodiments, the precursor supply unit may further include a bubbling gas supply device for supplying an inert gas to introduce the tungsten chloride into the chamber.

In other embodiments, the bubbling gas supply device may supply the inert gas so that the inert gas within the chamber has a flow rate of about 10 sccm to about 20 sccm.

In still other embodiments, the precursor supply unit may supply the tungsten chloride into the chamber so that the tungsten chloride within the chamber has a partial pressure of about 0.01 torr to about 0.02 torr.

In even other embodiments, the reactant supply unit may supply the hydrogen sulfide into the chamber so that the hydrogen sulfide within the chamber has a partial pressure of about 0.05 torr to about 0.15 torr.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a flowchart of a method for forming a tungsten sulfide layer according to an embodiment of the present invention;

FIG. 2 is a schematic cross-sectional view of an apparatus for forming the tungsten sulfide layer according to an embodiment of the present invention;

FIGS. 3A-3C are graphs illustrating results obtained by measuring a binding energy distribution of tungsten (W), sulfur (S), and chlorine (Cl) with respect to a tungsten sulfide layer formed according to Embodiment 1 of the present invention;

FIGS. 4A-4B are photographs obtained by photographing the tungsten sulfide layer formed according to Embodiment 1 of the present invention by using a transmission electron microscope;

FIG. 5 is a graph illustrating results obtained by measuring contrast depending on a distance on the basis of the transmission electron microscope photograph of FIG. 4;

FIGS. 6A-6B are a plan view (a) and cross-sectional view (b) obtained by photographing the tungsten sulfide layer formed according to Embodiment 1 of the present invention by using an optical microscope and an atomic force microscope, respectively;

FIG. 7 is a graph illustrating results obtained by measuring a distance-varying height distribution of the tungsten sulfide layer formed according to Embodiment 1 of the present invention;

FIGS. 8A-8B are a plan view (a) and cross-sectional view (b) obtained by photographing a tungsten sulfide layer formed according to Embodiment 2 of the present invention by using an optical microscope and an atomic force microscope, respectively;

FIG. 9 is a graph illustrating results obtained by measuring a distance-varying height distribution of the tungsten sulfide layer formed according to Embodiment 2 of the present invention;

FIGS. 10A-10C are graphs illustrating results obtained by measuring a binding energy distribution of tungsten (W), sulfur (S), and chlorine (Cl) with respect to a tungsten sulfide layer formed according to Embodiment 3 of the present invention;

FIGS. 11A-11B is a plan view (a) and cross-sectional view (b) obtained by photographing the tungsten sulfide layer formed according to Embodiment 3 of the present invention by using an optical microscope and an atomic force microscope, respectively;

FIG. 12 is a graph illustrating results obtained by measuring a distance-varying height distribution of the tungsten sulfide layer formed according to Embodiment 3 of the present invention;

FIGS. 13A-13B are a plan view (a) and cross-sectional view (b) obtained by photographing a tungsten sulfide layer formed according to Embodiment 4 of the present invention by using an optical microscope and an atomic force microscope, respectively;

FIG. 14 is a graph illustrating results obtained by measuring a distance-varying height distribution of the tungsten sulfide layer formed according to Embodiment 4 of the present invention; and

FIG. 15 is a graph illustrating a deviation in thickness of a tungsten sulfide layer depending on a partial pressure of tungsten chloride.

### DETAILED DESCRIPTION OF PREFERRED EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Unless otherwise defined, all terms (including technical and scientific terms) used herein have the same meaning as generally understood by those skilled in the art. Moreover, detailed descriptions related to well-known functions or configurations will be ruled out in order not to unnecessarily obscure subject matters of the present invention. It is also noted that like reference numerals denote like elements in appreciating the drawings.

In a method for forming a tungsten sulfide layer according to an embodiment of the present invention, a method for uniformly growing a tungsten sulfide layer on a substrate having a large area through atomic layer deposition using a new precursor and reactant and an apparatus for performing the same are disclosed. The method for forming the tungsten sulfide layer according to an embodiment of the present invention may use gaseous tungsten hexachloride ((WCl₆(g)) as the precursor for the atomic layer deposition and use hydrogen sulfide (H₂S(g)) as the reactant.

According to an embodiment of the present invention, to obtain the gasified tungsten chloride (WCl₆(g)), tungsten chloride (WCl₆(s)) having a solid state may be heated to form the gasified tungsten chloride, and then, the gasified tungsten chloride may be introduced into a chamber by bubbling an inert gas. According to an embodiment of the present invention, the gasified tungsten chloride within the chamber may have a partial pressure of about 0.01 torr to about 0.02 torr. According to an embodiment of the present invention, the hydrogen sulfide within the chamber may have a partial pressure of about 0.05 torr to about 0.15 torr. According to an embodiment of the present invention, the tungsten sulfide layer may be uniformly formed on a substrate having a large area. Each of tungsten sulfide molecular layers constituting the tungsten sulfide layer formed according to an embodiment of the present invention may have a thickness deviation of about 0.3 nm or less.

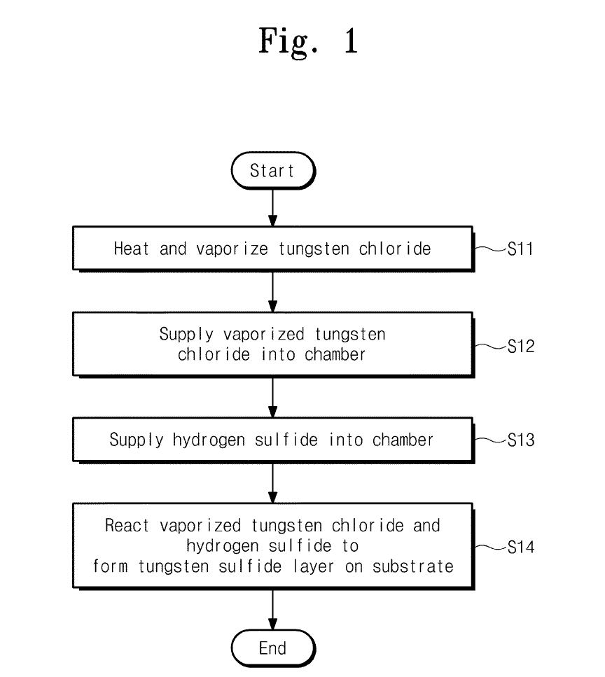

FIG. 1 is a flowchart of a method for a tungsten sulfide layer according to an embodiment of the present invention. In a method for forming a tungsten sulfide layer according to an embodiment of the present invention, a tungsten sulfide layer is formed on a substrate through atomic layer deposition. In the method for forming the tungsten sulfide layer according to an embodiment, when the tungsten sulfide layer is formed through the atomic layer deposition, gasified tungsten chloride (WCl₆(g)) and hydrogen sulfide (H₂S) are used. Referring to FIG. 1, to obtain the gasified tungsten chloride that is used as a precursor when the atomic layer deposition is performed, tungsten chloride having a solid state may be heated and thus gasified in operation S11.

For example, to gasify the tungsten chloride in the operation S11, the tungsten chloride may be heated at a temperature of about 60° C. or more to generate the gasified tungsten chloride. Although chloride has a boiling point of about 347° C., a portion of the tungsten chloride may be gasified under a temperature of about 60° C. The gasified tungsten chloride may be supplied into the chamber and utilized as the precursor. When the tungsten chloride is heated at a temperature grater than that of about 100° C., an amount of vaporized tungsten chloride may unnecessarily increase. Thus, when the large amount of gasified tungsten chloride is supplied into the chamber, the tungsten sulfide layer may not be adsorbed in the form of a layer on the substrate, and also, it may be difficult to obtain a uniform tungsten sulfide layer. Thus, the tungsten chloride may be heated at an adequate temperature of about 60° C. to about 100° C.

In operation S12, the gasified tungsten chloride that is used as the precursor is supplied into the chamber so as to perform the atomic layer deposition. Here, the gasified tungsten chloride may be supplied into the camber so that the gasified tungsten chloride within the chamber has a partial pressure of about 0.01 torr to about 0.02 torr. If the gasified tungsten chloride has a partial pressure less than about 0.01 torr, the tungsten sulfide layer may not be formed well on the substrate, or the tungsten sulfide layer may have a relatively large thickness deviation even though the tungsten sulfide layer is formed on the substrate, and may not be formed uniformly over a large area. If the gasified tungsten chloride has a partial pressure greater than about 0.02 torr, the more the partial pressure of the gasified tungsten chloride increases, the more the thickness deviation of the tungsten sulfide layer may increase.

Thus, to form the tungsten sulfide on the large area uniformly, it may be necessary to control the partial pressure of the tungsten chloride within the chamber to a pressure of about 0.01 torr to about 0.02 torr. According to a test performed by the inverter, when the partial pressure of the tungsten chloride is controlled to a pressure of about 0.03 torr, the tungsten sulfide may have a thickness deviation of about 1.0 nm. However, when the partial pressure of the tungsten chloride is controlled to a pressure of about 0.01 torr to about 0.02 torr, the tungsten sulfide may have a thickness deviation of about 0.3 nm or less. Thus, it is confirmed that the thickness deviation of the tungsten sulfide may be reduced to approximately ⅓.

In the operation S12, an inert gas may be bubbled so that the gasified tungsten chloride is smoothly introduced into the chamber. According to an embodiment of the present invention, the inert gas may be adjusted in flow rate to control the partial pressure of the gasified tungsten chloride within the chamber to a pressure of about 0.01 torr to about 0.02 torr. For example, an argon or nitrogen gas or a mixture thereof may be used as the bubbling gas. In the bubbling of the inert gas, the inert gas may be bubbled so that the inert gas within the chamber has a flow rate of about 10 sccm to about 20 sccm. In an embodiment of the present invention, since the inert gas is bubbled so that the inert gas within the chamber has a flow rate of about 10 sccm to about 20 sccm, the gasified tungsten chloride within the chamber may be controlled to a pressure of about 0.01 torr to about 0.02 torr.

In operation S13, hydrogen sulfide as a reactant is supplied into the chamber. Here, the hydrogen sulfide may be supplied into the chamber so that the hydrogen sulfide within the chamber has a partial pressure of about 0.05 torr to about 0.15 torr. When the hydrogen sulfide has a partial pressure of about 0.05 torr or less, the tungsten sulfide may not be formed well on the substrate. On the other hand, when the hydrogen sulfide has a partial pressure of about 0.15 torr or more, the tungsten sulfide may increase in thickness deviation due to unbalance in mol ratio with tungsten chloride. The operations S12 and S13 may not be performed in time sequence, but be performed at the same time. In case of using the previously gasified tungsten chloride, the operation S11 may be omitted.

When the gasified tungsten chloride and the hydrogen sulfide are supplied into the chamber in the operations S12 and S13, a tungsten sulfide layer may be formed on the substrate due to reaction between the tungsten chloride and the hydrogen sulfide. Here, the substrate may have a temperature of about 400° C. to about 800° C. This is done because the tungsten sulfide is smoothly synthesized when the substrate has a temperature of about 400° C. to about 800° C. The substrate may be a silicon (Si) substrate or a silicon oxide (SiO₂) substrate. The substrate may be previously heated before the precursor or reactant is supplied. Alternatively, the substrate may be heated after or while the precursor or reactant is supplied. The tungsten chloride and the hydrogen sulfide may react with each other according to the following reaction formula 1 and then be synthesized into tungsten sulfide (WS₂(s)).

WCl₆(g)+H₂S(g)->WS₂(s)+6HCl(g) [Reaction Formula 1]

Chlorine of tungsten chloride adsorbed to a substrate and sulfur composing of hydrogen sulfide exchange-react with each other to form a tungsten sulfide molecular layer on the substrate. In an embodiment of the present invention, the process (S11 to S12) of supplying the precursor and the process (S13) of supplying the reactant may be repeatedly performed several times to form a tungsten sulfide layer including at least one tungsten sulfide molecular layer on the substrate. According to an embodiment of the present invention, the tungsten sulfide layer may be formed with a mean thickness of about 0.6 nm to about 60 nm. However, in the method for forming the tungsten sulfide layer according to an embodiment of the present invention, the tungsten sulfide layer may be formed with a thickness greater than about 60 nm. According to an embodiment of the present invention, the tungsten sulfide layer may be formed by stacking the nano-scaled tungsten sulfide molecular layers, and thus, the tungsten sulfide layer may be adjusted in thickness to the nano-scale.

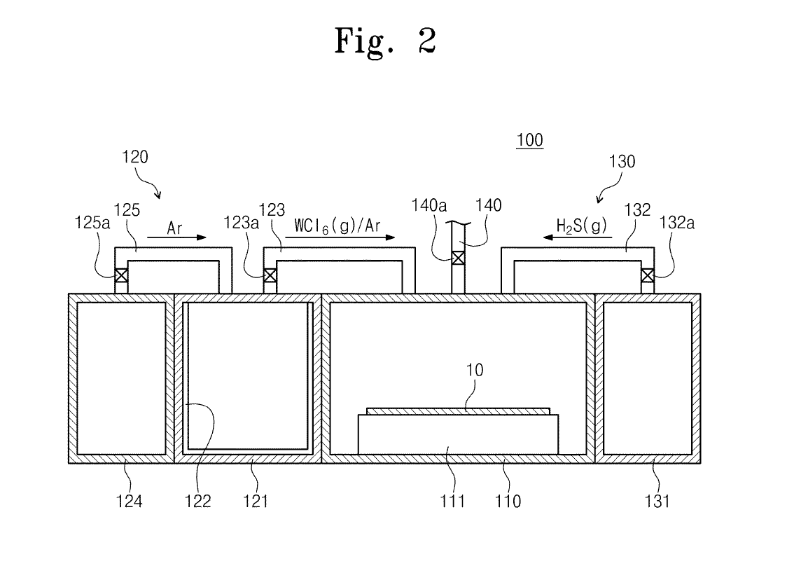

FIG. 2 is a schematic cross-sectional view of the apparatus for forming the tungsten sulfide layer according to an embodiment of the present invention. Referring to FIG. 2, the apparatus 100 for forming the tungsten sulfide layer according to an embodiment of the present invention includes a chamber 110, a precursor supply unit 120, and a reactant supply unit 130. The apparatus 100 for forming the tungsten sulfide layer may form the tungsten sulfide layer through the atomic layer deposition.

The chamber 110 has an empty space into which the precursor and the reactant are supplied. The chamber 110 receives the precursor through a precursor supply tube 123 and receives the reactant through a reactant supply tube 132. The chamber 110 may be configured to support a substrate 10 in the inner space thereof. A substrate heating device 111 may be disposed in the chamber 110. The substrate heating device 111 may heat the substrate 10 at a predetermined temperature that is required for forming a uniform tungsten sulfide layer. The substrate heating device 111 may maintain the substrate 10 at a temperature of about 400° C. to about 800° C. so that synthesis of the tungsten sulfide is smoothly performed. The substrate 10 may be a silicon (Si) substrate or silicon oxide (SiO₂) substrate, but is not limited thereto.

The precursor supply unit 120 may supply the precursor including gasified tungsten chloride (WCl₆) into the chamber 110. The precursor supply unit 120 may supply the precursor into the chamber 110 through the precursor supply tube 123. An amount of precursor supplied from the precursor supply unit 120 into the chamber 110 may be adjusted through a valve 123a disposed in the precursor supply tube 123. According to an embodiment, the valve 123a may be controlled in opening/closing and adjusted in opening degree according to a pressure of the tungsten chloride measured by a sensor (not shown) within the chamber 110. For example, the control unit (not shown) may wiredly/wirelessly receive a value measured by the sensor to control the valve 123a according to the received value measured by the sensor.

The precursor supply unit 120 may supply the precursor including the gasified tungsten chloride into the chamber 110 so that the gasified tungsten chloride has a partial pressure of about 0.01 torr to about 0.02 torr. If the gasified tungsten chloride has a partial pressure less than about 0.01 torr, the tungsten sulfide layer may not be well formed on the substrate 10, or the tungsten sulfide layer may have a relatively large thickness deviation on the substrate even though the tungsten sulfide layer is formed. Thus, it may be difficult to uniformly form the tungsten sulfide layer over a large area. If the gasified tungsten chloride has a partial pressure greater than about 0.02 torr, the more the partial pressure of the gasified tungsten chloride increases, the more the thickness deviation of the tungsten sulfide layer may increase. Thus, to uniformly form the tungsten sulfide layer on the large area of the substrate 10, the partial pressure of the tungsten chloride within the chamber may be controlled to a pressure of about 0.01 torr to about 0.02 torr. When the partial pressure of the tungsten chloride is controlled to a pressure of about 0.01 torr to about 0.02 torr, the thickness deviation of the tungsten sulfide may be reduced to approximately ⅓ when compared to the tungsten chloride having the partial pressure greater than about 0.02 torr.

According to an embodiment of the present invention, the precursor supply unit 120 may include a heating device 122 and a bubbling gas supply device 124. For example, the heating device 122 may be provided on a wall of the precursor supply unit 120 having the form of a tank 121. The heating device 122 may heat tungsten chloride having a solid state through radiation, conduction, or convection to generate the gasified tungsten chloride. According to an embodiment of the present invention, to uniformly form the tungsten sulfide layer on the large area of the substrate 10, the heating device 122 may heat the tungsten chloride at a temperature of about 60° C. to about 100° C. The precursor supply unit 120 may include a sensor (not shown) for measuring a temperature of the tungsten chloride. Also, the heating device 122 may be controlled in operation under the control of the control unit (not shown) according to a temperature value measured by the sensor.

The bubbling gas supply device 124 supplies an inert gas, for example, an argon gas or nitrogen gas into the precursor supply unit 120. The inert gas may be supplied into the tank 121 for storing the tungsten chloride of the precursor supply unit 120 through the bubbling gas supply device 124 to smoothly introduce the gasified tungsten chloride into the chamber 110. The bubbling gas, i.e., the inert gas may be bubbled to smoothly vaporize the tungsten chloride and also may induce the gasified tungsten chloride into the chamber 110.

A supply amount of inert gas may be adjusted by a valve 125a disposed in the bubbling gas supply tube 125. The bubbling gas supply device 124 may supply the inert gas into the tank 121 so that the inert gas within the chamber 110 has a flow rate of about 10 sccm to about 20 sccm. For example, when the inert gas within the chamber 110 has a flow rate less than about 10 sccm, the valve 125a may be opened or increase in opening degree to increase the supply amount of inert gas. On the other hand, when the inert gas within the chamber 110 has a flow rate greater than about 20 sccm, the valve 125a may be closed or reduced in opening degree to reduce the supply amount of inert gas. For this, a sensor (not shown) for measuring the flow rate of the inert gas may be provided in the chamber 110.

According to an embodiment of the present invention, the inert gas may be adjusted in flow rate to control the partial pressure of the gasified tungsten chloride within the chamber 110 to a pressure of about 0.01 torr to about 0.02 torr. That is, since an amount of tungsten chloride induced into the chamber 110 varies according to the flow rate of the inert gas, the flow rate of the inert gas may be adjusted to adjust the partial pressure of the gasified tungsten chloride within the chamber 110. For example, the inert gas used as the bubbling gas may include an argon gas or nitrogen gas.

The reactant supply unit 130 supplies the reactant including hydrogen sulfide into the chamber 110. According to an embodiment of the present invention, the reactant supply unit 130 may supply the reactant through the reaction supply tube 132 from a reaction storage tank 131 to the chamber 110. An amount of reactant supplied from the reactant supply unit 130 to the chamber 110 may be adjusted by opening a valve 132a disposed in the reactant supply tube 132 or adjusting an opening degree of the valve 132a. The reactant supply unit 130 may supply the hydrogen sulfide into the chamber 110 so that the hydrogen sulfide within the chamber 110 has a partial pressure of about 0.05 torr to about 0.15 torr. When the hydrogen sulfide within the chamber 110 has a partial pressure less than about 0.05 torr, the tungsten sulfide may not be well formed on the substrate 10. On the other hand, when the hydrogen sulfide within the chamber 110 has a partial pressure greater than about 0.15 torr, the tungsten sulfide may increase in thickness deviation due to unbalance in mol ratio with tungsten chloride. When the gasified tungsten chloride and the hydrogen sulfide are supplied into the chamber 110, a tungsten sulfide layer may be formed on the substrate 10 due to the reaction between the tungsten chloride and the hydrogen sulfide within the chamber 110. The tungsten chloride and the hydrogen sulfide may react with each other according to the foregoing reaction formula 1 and then be synthesized into tungsten sulfide (WS₂(s)).

In an embodiment of the present invention, the process of supplying the precursor by the precursor supply unit 120 and the process of supplying the reactant by the reactant supply unit 130 may be repeatedly performed several times to form a tungsten sulfide layer including at least one tungsten sulfide molecular layer on the substrate 10. In an embodiment of the present invention, the processes of supplying the precursor and the reactant are performed once, a valve 140a and a pump (not shown) may operate to discharge materials remaining after the reaction through an exhaust part 140. Then, the valve 140a may be closed to perform the processes of supplying the precursor and the reactant again, thereby forming the tungsten sulfide layer on the substrate 10.

Since the tungsten sulfide has high electron mobility, the tungsten sulfide may be substituted for LTPS and IGZO materials that are used for the present thin film transistor. Also, since the tungsten sulfide has a flexible property, the tungsten sulfide may be utilized for the flexible thin film transistor. Thus, the tungsten sulfide may be adequate for realizing flexible displays, TFT display devices, and the like. Also, according to an embodiment of the present invention, the tungsten sulfide layer may be easily adjusted in thickness.

### Embodiment 1

A test for forming a tungsten sulfide layer on a substrate through atomic layer deposition was performed. The substrate was loaded into a chamber to perform the atomic layer deposition and then was heated at a temperature of about 700° C. Here, a substrate in which silicon oxide that is an insulation material is formed on a silicon base material was used as the substrate. To use gasified tungsten chloride as a precursor, tungsten chloride having a solid state was heated at a temperature of about 80° C. and thus gasified. Then, the gasified tungsten chloride was supplied into the chamber for performing the atomic layer deposition. Here, the gasified tungsten chloride within the chamber has a partial pressure of about 0.015 torr. An argon (Ar) gas was bubbled to smoothly introduce the gasified tungsten chloride into the chamber. Hydrogen sulfide as a reactant was supplied into the chamber. Here, the hydrogen sulfide within the chamber has a partial pressure of about 0.1 torr. A process of allowing the gasified tungsten chloride to react with the hydrogen sulfide after the precursor and reactant are supplied into the chamber may be defined as one cycle. The 50 cycles were repeatedly performed to form a tungsten sulfide layer composed of one tungsten sulfide molecular layer.

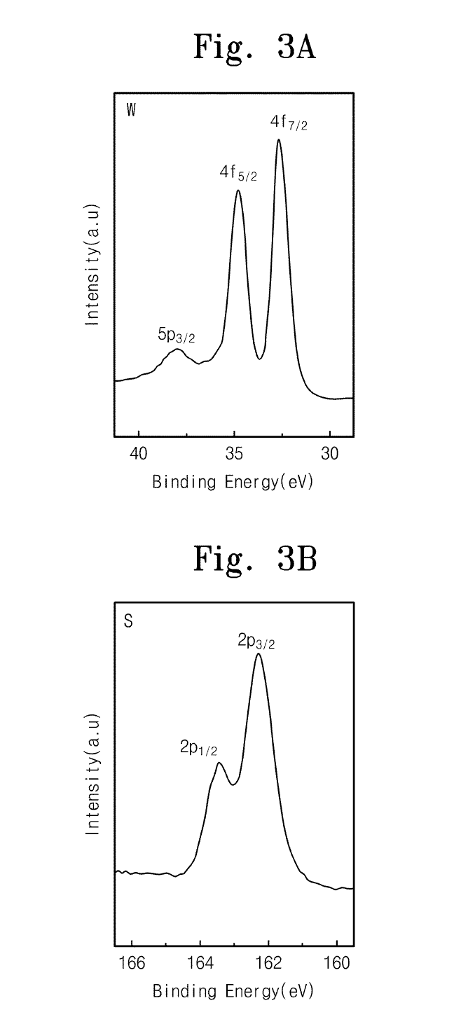

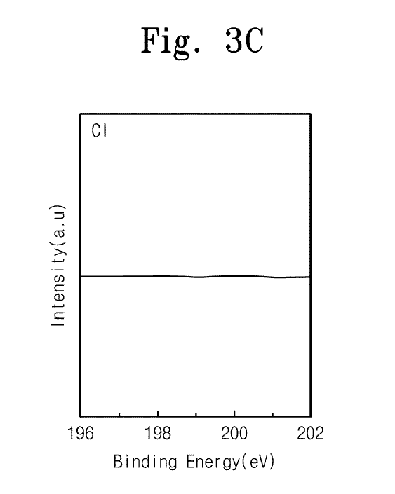

FIG. 3 is a graph illustrating results obtained by measuring a binding energy distribution of tungsten (W), sulfur (S), and chlorine (Cl) with respect to the tungsten sulfide layer formed according to Embodiment 1 of the present invention. The binding energy distribution was measured by using an X-ray photoelectron spectroscopy (XPS) method. In case of the binding energy distribution of tungsten (W), binding energy has peaks at points 4f7/2, 4f5/2, and 5p3/2 as illustrated in FIG. 3A. In case of the binding energy distribution of sulfur (S), binding energy has peaks at points 2p3/2 and 2p1/2 as illustrated in FIG. 3B. In case of the binding energy distribution of chlorine (Cl), binding energy does not have a peak as illustrated in FIG. 3C. Thus, it is seen that the chlorine (Cl) of the tungsten chloride adsorbed to the substrate is substituted for the hydrogen sulfide and sulfur (S) to form the tungsten sulfide layer. When mol ratios of tungsten (W), sulfur (S), and chlorine (Cl) are analyzed from the binding energy intensity of tungsten and sulfur, ratios (33.6/66.4/0) similar to theoretical ratios (1/2/0) were measured.

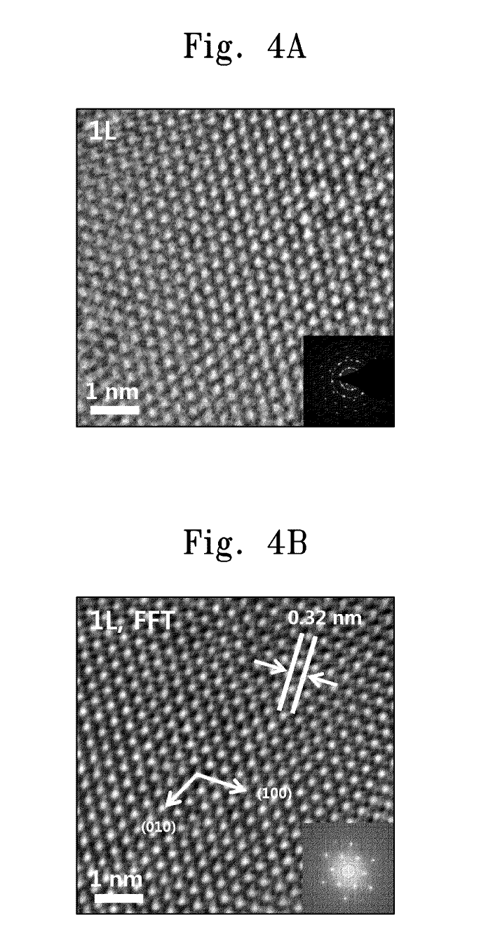

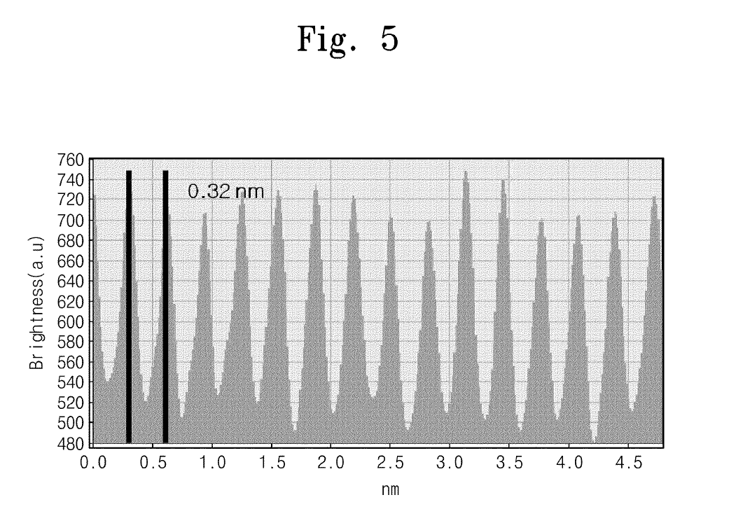

FIG. 4 is a view illustrating photographs that are photographed by using a transmission electron microscope with respect to the tungsten sulfide layer formed according to Embodiment 1 of the present invention. In the photograph shown in FIGS. 4A and 4B, white points represent sulfur elements, and a tungsten atom is disposed at a center of three sulfur elements adjacent to each other. As illustrated in FIG. 4B, the sulfur elements are arranged alone a (1,0,0) orientation and (0,1,0) orientation. FIG. 5 is a graph illustrating results obtained by measuring contrast depending on a distance on the basis of the transmission electron microscope photograph of FIG. 4. In FIG. 5, peaks are expressed as bright areas on the transmission electron microscope photograph. As illustrated in FIGS. 4B and 5, a distance, i.e., a lattice constant between the sulfur elements adjacent to each other was measured to about 0.32 nm that corresponds to the theoretical lattice constant of the tungsten sulfide.

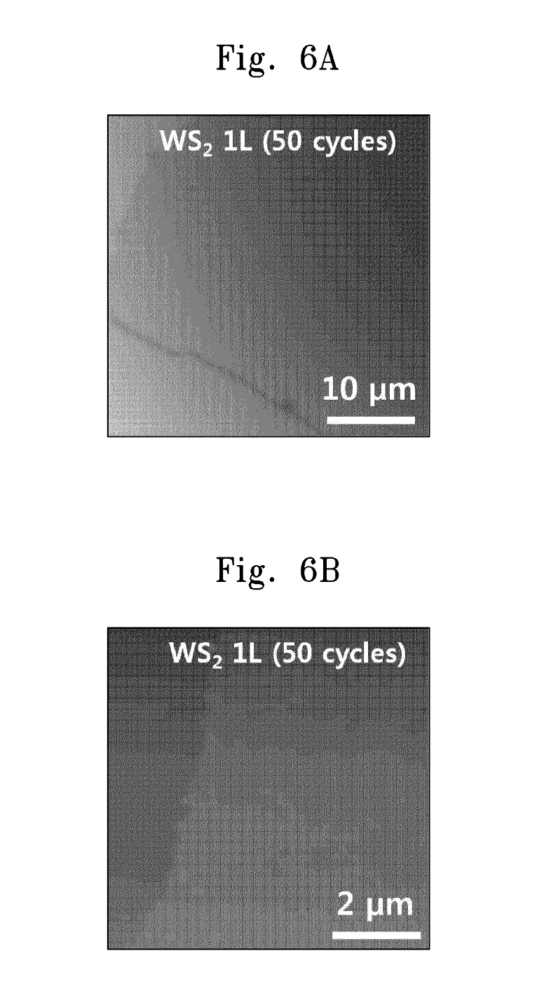

FIG. 6 is a plan view (a) illustrating a photograph that is photographed by using an optical microscope and a cross-sectional view (b) illustrating a photograph that is photographed by an atomic force microscope (AFM) with respect to the tungsten sulfide layer formed according to Embodiment 1 of the present invention. In FIG. 6A, a relatively deepen portion represents an area on which a tungsten sulfide layer is formed on a substrate, and a relatively lighten portion represents an area from which the tungsten sulfide layer is peeled. In FIG. 6B, a relatively deepen portion represents an area from which the tungsten sulfide layer is peeled, and a relatively lighten portion represents an area on which the tungsten sulfide layer is formed on a substrate.

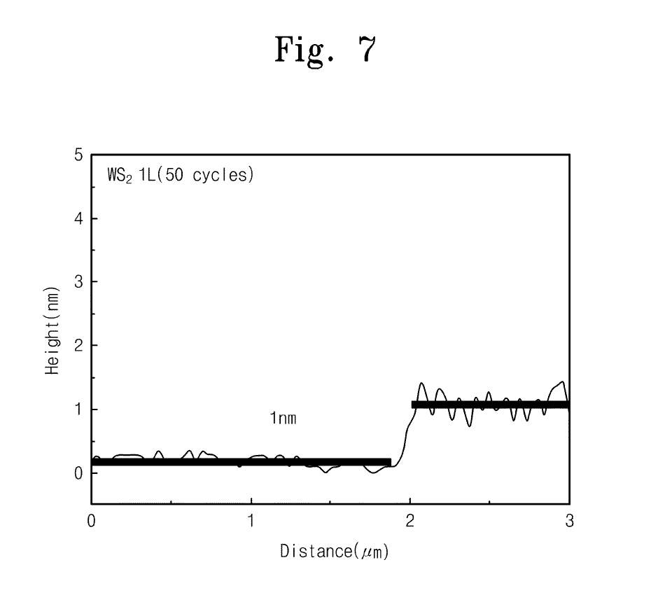

FIG. 7 is a graph illustrating results obtained by measuring a distance-varying height distribution of the tungsten sulfide layer formed according to Embodiment 1 of the present invention. Referring to FIG. 7, an area that is spaced a distance of about 2 μm or less from a reference position corresponds to a portion from which the tungsten sulfide layer is peeled, and an area that is spaced a distance of about 2 μm or more from the reference position corresponds to a portion on which the tungsten sulfide layer is formed on the substrate. Referring to FIG. 7, the tungsten sulfide formed according to Embodiment 1 of the present invention has a mean thickness of approximately 1.0 nm. When a standard deviation with respect to a height distribution of the tungsten sulfide layer is calculated and measured, the tungsten sulfide layer formed according to Embodiment 1 has a thickness deviation less than approximately 0.3 nm.

### Embodiment 2

A test for forming a tungsten sulfide layer on a substrate through atomic layer deposition was performed. Here, a tungsten sulfide composed of two tungsten sulfide molecular layers was formed under the same test conditions as Embodiment 1 except that the process of allowing the gasified tungsten chloride to react with the hydrogen sulfide after the precursor and reactant are supplied into the chamber is performed in 100 cycles.

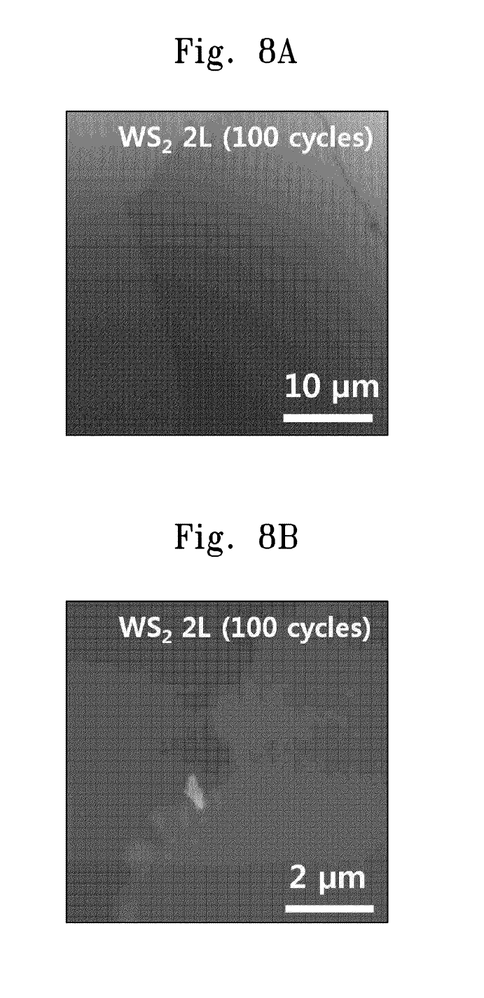

FIG. 8 is a plan view (a) illustrating a photograph that is photographed by using an optical microscope and a cross-sectional view (b) illustrating a photograph that is photographed by an atomic force microscope (AFM) with respect to the tungsten sulfide layer formed according to Embodiment 2 of the present invention. In FIG. 8A, a relatively deepen portion represents an area on which a tungsten sulfide layer is formed on a substrate, and a relatively lighten portion represents an area from which the tungsten sulfide layer is peeled. In FIG. 8B, a relatively deepen portion represents an area from which the tungsten sulfide layer is peeled, and a relatively lighten portion represents an area on which the tungsten sulfide layer is formed on a substrate.

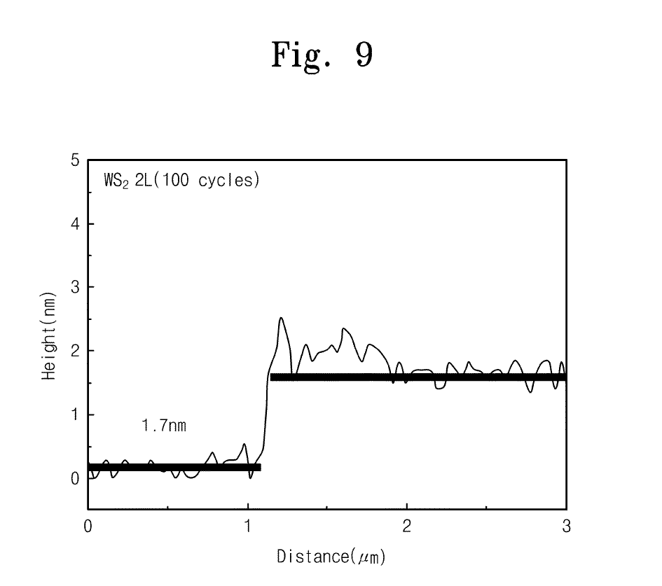

FIG. 9 is a graph illustrating results obtained by measuring a distance-varying height distribution of the tungsten sulfide layer formed according to Embodiment 2 of the present invention. Referring to FIG. 9, an area that is spaced a distance of about 1.2 μm or less from a reference position corresponds to a portion from which the tungsten sulfide layer is peeled, and an area that is spaced a distance of about 1.2 μm or more from the reference position corresponds to a portion on which the tungsten sulfide is formed on the substrate. Referring to FIG. 9, the tungsten sulfide formed according to Embodiment 2 of the present invention has a mean thickness of approximately 1.7 nm. When a standard deviation with respect to a height distribution of the tungsten sulfide layer is calculated and measured, one tungsten sulfide molecular layer in the tungsten sulfide layer formed according to Embodiment 2 has a thickness deviation less than approximately 0.3 nm.

### Embodiment 3

A test for forming a tungsten sulfide layer on a substrate through atomic layer deposition was performed. Here, a tungsten sulfide composed of four tungsten sulfide molecular layers was formed under the same test conditions as Embodiment 1 except that the process of allowing the gasified tungsten chloride to react with the hydrogen sulfide after the precursor and reactant are supplied into the chamber is performed in 200 cycles.

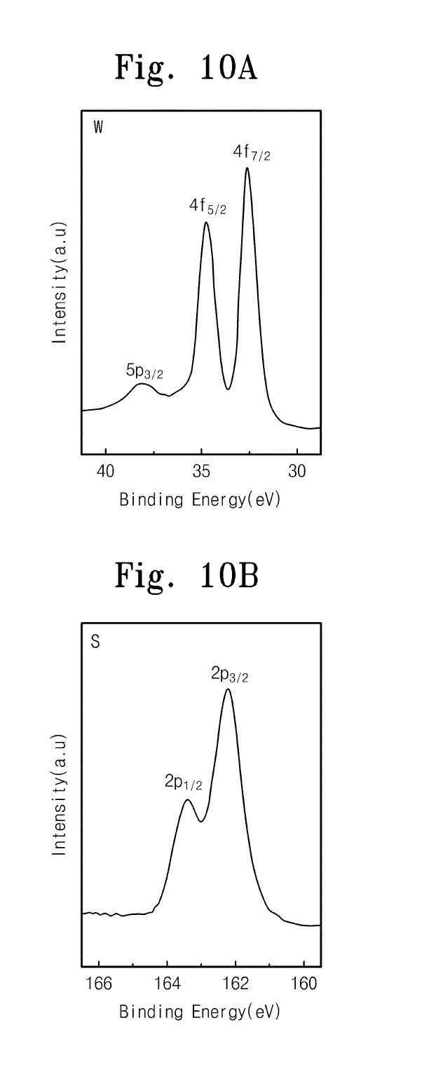

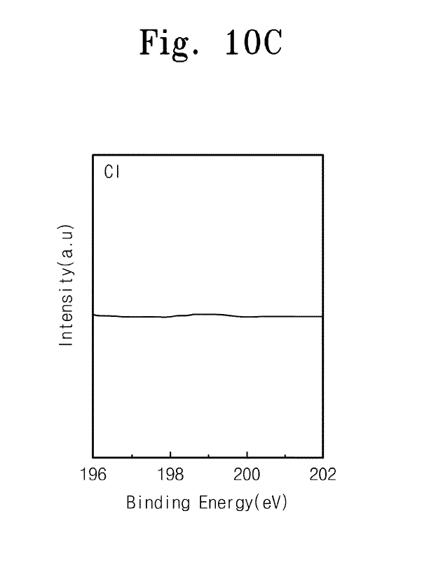

FIG. 10 is a graph illustrating results obtained by measuring a binding energy distribution of tungsten (W), sulfur (S), and chlorine (Cl) with respect to the tungsten sulfide layer formed according to Embodiment 3 of the present invention. The binding energy distribution was measured by using an X-ray photoelectron spectroscopy (XPS) method. In case of the binding energy distribution of tungsten (W), binding energy has peaks at points 4f7/2, 4f5/2, and 5p3/2 as illustrated in FIG. 10A. In case of the binding energy distribution of sulfur (S), binding energy has peaks at points 2p3/2 and 2p1/2 as illustrated in FIG. 10B. In case of the binding energy distribution of chlorine (Cl), binding energy does not have a peak as illustrated in FIG. 10C. Thus, it is seen that the chlorine (Cl) of the tungsten chloride adsorbed to the substrate is substituted for the hydrogen sulfide and sulfur (S) to form the tungsten sulfide layer. When mol ratios of tungsten (W), sulfur (S), and chlorine (Cl) are analyzed from the binding energy intensity of tungsten and sulfur, ratios (33.1/67.0/0) similar to theoretical ratios (1/2/0) were measured.

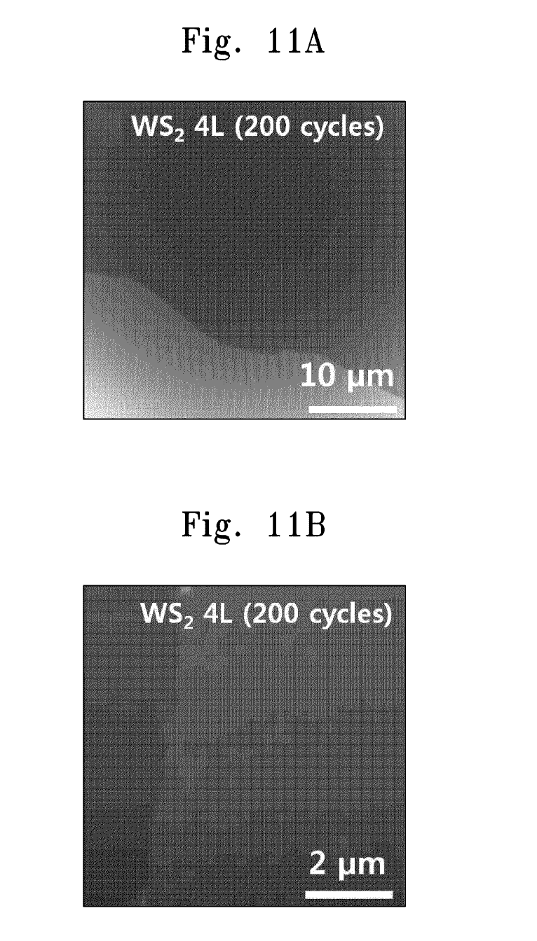

FIG. 11 is a plan view (a) illustrating a photograph that is photographed by using an optical microscope and a cross-sectional view (b) illustrating a photograph that is photographed by an atomic force microscope (AFM) with respect to the tungsten sulfide layer formed according to Embodiment 3 of the present invention. In FIG. 11A, a relatively deepen portion represents an area on which a tungsten sulfide layer is formed on a substrate, and a relatively lighten portion represents an area from which the tungsten sulfide layer is peeled. In FIG. 11B, a relatively deepen portion represents an area from which the tungsten sulfide layer is peeled, and a relatively lighten portion represents an area on which the tungsten sulfide layer is formed on a substrate.

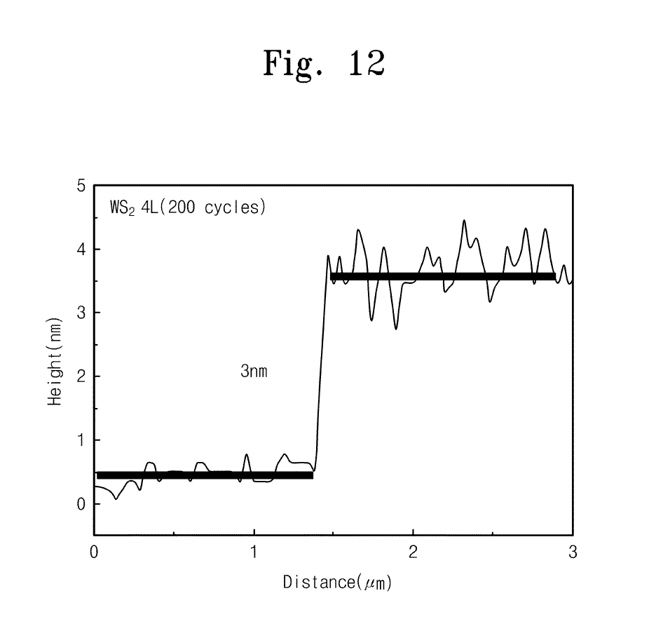

FIG. 12 is a graph illustrating results obtained by measuring a distance-varying height distribution of the tungsten sulfide layer formed according to Embodiment 3 of the present invention. Referring to FIG. 12, an area that is spaced a distance of about 1.4 μm or less from a reference position corresponds to a portion from which the tungsten sulfide layer is peeled, and an area that is spaced a distance of about 1.4 μm or more from the reference position corresponds to a portion on which the tungsten sulfide is formed on the substrate. Referring to FIG. 12, the tungsten sulfide formed according to Embodiment 3 of the present invention has a mean thickness of approximately 3.0 nm. When a standard deviation with respect to a height distribution of the tungsten sulfide layer is calculated and measured, one tungsten sulfide molecular layer in the tungsten sulfide layer formed according to Embodiment 3 has a thickness deviation less than approximately 0.3 nm.

### Embodiment 4

A test for forming a tungsten sulfide layer on a substrate through atomic layer deposition was performed. Here, a tungsten sulfide composed of a plurality of tungsten sulfide molecular layers (about 40 layers) was formed under the same test conditions as Embodiment 1 except that the process of allowing the gasified tungsten chloride to react with the hydrogen sulfide after the precursor and reactant are supplied into the chamber is performed in 2,000 cycles.

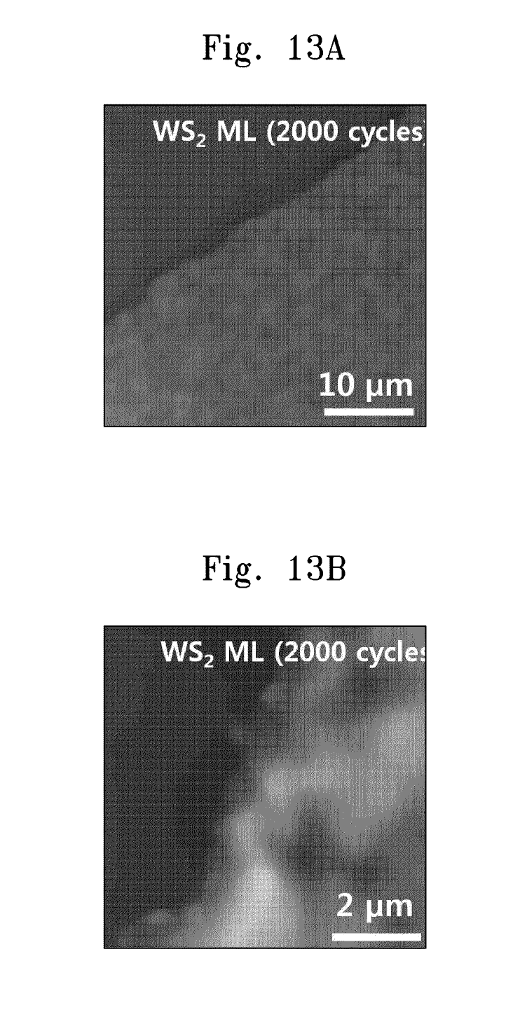

FIG. 13 is a plan view (a) illustrating a photograph that is photographed by using an optical microscope and a cross-sectional view (b) illustrating a photograph that is photographed by an atomic force microscope (AFM) with respect to the tungsten sulfide layer formed according to Embodiment 4 of the present invention. In FIG. 13A, a relatively deepen portion represents an area on which a tungsten sulfide layer is formed on a substrate, and a relatively lighten portion represents an area from which the tungsten sulfide layer is peeled. In FIG. 13B, a relatively deepen portion represents an area from which the tungsten sulfide layer is peeled, and a relatively lighten portion represents an area on which the tungsten sulfide layer is formed on a substrate.

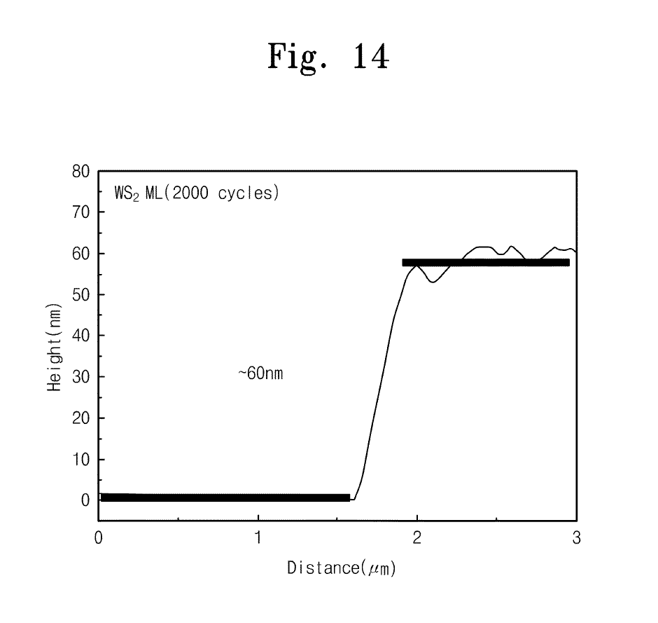

FIG. 14 is a graph illustrating results obtained by measuring a distance-varying height distribution of the tungsten sulfide layer formed according to Embodiment 4 of the present invention. Referring to FIG. 14, an area that is spaced a distance of about 1.7 μm or less from a reference position corresponds to a portion from which the tungsten sulfide layer is peeled, and an area that is spaced a distance of about 1.7 μm or more from the reference position corresponds to a portion on which the tungsten sulfide is formed on the substrate. Referring to FIG. 14, the tungsten sulfide formed according to Embodiment 4 of the present invention has a mean thickness of approximately 60 nm. When a standard deviation with respect to a height distribution of the tungsten sulfide layer is calculated and measured, one tungsten sulfide molecular layer in the tungsten sulfide layer formed according to Embodiment 4 has a thickness deviation less than approximately 0.3 nm.

### Embodiment 5

A test for confirming an effect in which a pressure of tungsten chloride within a chamber has an influence on a thickness deviation of a tungsten sulfide layer in the method for forming a tungsten sulfide layer on a substrate through atomic layer deposition was performed. The substrate was loaded into a chamber to perform the atomic layer deposition and then was heated at a temperature of about 700° C. Here, a substrate in which silicon oxide that is an insulation material is formed on a silicon base material was used as the substrate. To use gasified tungsten chloride as a precursor, tungsten chloride having a solid state was heated at a temperature of about 80° C. and thus gasified. Then, the gasified tungsten chloride was supplied into the chamber for performing the atomic layer deposition.

Here, a test was performed under various partial pressures while the gasified tungsten chloride within the chamber varies in partial pressure by about 0.005 torr in ranging from about 0.005 torr to about 0.03 torr. Here, an argon (Ar) gas was bubbled to smoothly introduce the gasified tungsten chloride into the chamber. Also, a supply amount of argon gas may vary to easily adjust a partial pressure of the gasified tungsten chloride within the chamber. Hydrogen sulfide as a reactant was supplied into the chamber. Here, the hydrogen sulfide within the chamber has a partial pressure of about 0.1 torr. After the precursor and the reactant are supplied into the chamber, a cycle in which the gasified tungsten chloride and the hydrogen sulfide react with each other was repeatedly performed 50 times to form a tungsten sulfide layer and measure a thickness deviation of the tungsten sulfide layer according to the partial pressure of the tungsten chloride. Here, the measured results are expressed in Table 1. Here, a thickness deviation of the tungsten sulfide layer was measured by calculating a standard deviation with respect to a height distribution of the tungsten sulfide layer.

TABLE 1

| | Tungsten Chloride | Tungsten Sulfide layer | |
|---|---|---|---|
| | Partial Pressure | Thickness Deviation | |
| | (torr) | (nm) | Note |
| Experimental | 0.005 | 0.35 | Comparative |
| Example 1 | | | Example |
| Experimental | 0.010 | 0.28 | Inventive |
| Example 2 | | | Example |
| Experimental | 0.015 | 0.27 | Inventive |
| Example 4 | | | Example |
| Experimental | 0.020 | 0.30 | Inventive |
| Example 4 | | | Example |
| Experimental | 0.025 | 1.0 | Comparative |
| Example 5 | | | Example |
| Experimental | 0.030 | 1.4 | Comparative |
| Example 6 | | | Example |

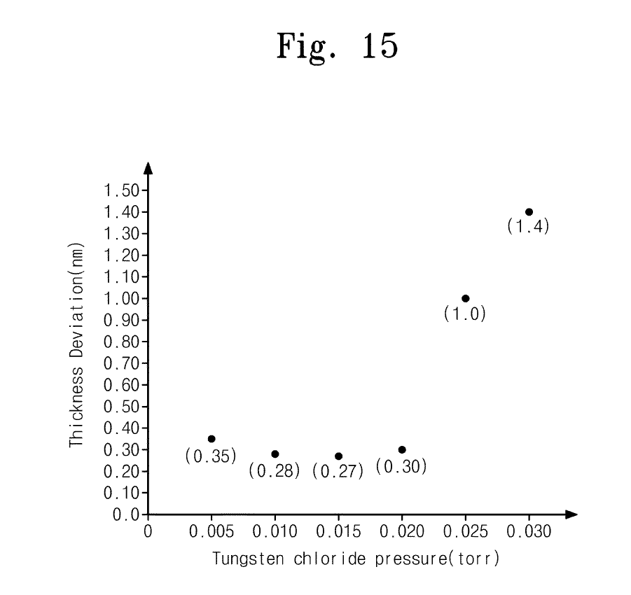

FIG. 15 is a graph illustrating a deviation in thickness of a tungsten sulfide layer depending on a partial pressure of tungsten chloride. Referring to Table 1 and FIG. 15, in case of Experimental Examples 2 to 4 in which the gasified tungsten chloride within the chamber has a partial pressure of about 0.01 torr to about 0.02 torr, the tungsten sulfide layer has a thickness deviation less than about 0.30 nm. In case of Experimental Example 1 in which the tungsten chloride has a partial pressure less than about 0.01 torr, the tungsten sulfide layer has a thickness deviation greater than about 0.30 nm. Also, according to the results observed by using an optical microscope, in case of the tungsten chloride having a partial pressure of about 0.01 torr, it is confirmed that the tungsten sulfide layer is not partially formed on the substrate. In case of Experimental Examples 5 and 6 in which the gasified tungsten chloride within the chamber has a partial pressure greater than 0.02 torr, it is seen that the tungsten sulfide layer increases in thickness deviation as the gasified tungsten chloride increases in partial pressure. This is done because two tungsten sulfide molecular layers are partially stacked on the substrate when the tungsten chloride has a partial pressure grater than about 0.02 torr.

According to the embodiments, the tungsten sulfide layer may be uniformly formed over the large area.

The effects of the present invention are not limited to the above-described effects, and unmentioned effects will be clearly understood by those skilled in the art from the specification and the accompanying drawings.

Following embodiments are provided to help understanding of the prevent invention, but do not limit the scope of the present invention, and thus those with ordinary skill in the technical field of the present invention pertains will be understood that the present invention can be carried out in other specific forms without changing the technical idea or essential features. Therefore, the technical scope of protection of the present invention will be determined by the technical idea of the scope of the appended claims, and also will be understood as not being limited to the literal description in itself, but reaching the equivalent technical values of the present invention.

What is claimed is:

1. A method for forming a tungsten sulfide layer by atomic layer deposition, the method comprising:
reacting a precursor comprising a gaseous tungsten chloride and a reactant comprising hydrogen sulfide to form a tungsten sulfide layer on a substrate.

2. The method of claim 1, further comprising heating a tungsten chloride of solid state to generate the precursor comprising the gaseous tungsten chloride.

3. The method of claim 2, wherein the heating the tungsten chloride of solid state comprises heating the tungsten chloride of solid state at a temperature of about 60° C. to about 100 r to generate the gaseous tungsten chloride.

4. The method of claim 1, wherein the tungsten sulfide layer comprises at least one tungsten sulfide molecular layer, each of the at least one tungsten sulfide molecular layer having a thickness deviation of about 0 nm to about 0.3 nm.

5. The method of claim 1, further comprising:
supplying the precursor comprising the gaseous tungsten chloride onto the substrate in a chamber; and
supplying the reactant comprising the hydrogen sulfide onto the substrate,
wherein the supplying the precursor and the supplying the reactant are repeatedly performed to form the tungsten sulfide layer comprising at least one tungsten sulfide molecular layer on the substrate.

6. The method of claim 5, wherein the supplying the precursor comprises supplying the gaseous tungsten chloride into the chamber so that the tungsten chloride within the chamber has a partial pressure of about 0.01 torr to about 0.02 torr.

7. The method of claim 6, wherein each of the at least one tungsten sulfide molecular layer has a thickness deviation of about 0 nm to about 0.3 nm.

8. The method of claim 5, wherein the supplying the precursor comprises bubbling an inert gas to introduce the gaseous tungsten chloride into the chamber.

9. The method of claim 8, wherein the inert gas comprises at least one selected from an argon gas and a nitrogen gas, and
the bubbling the inert gas comprises bubbling the inert gas so that the inert gas within the chamber has a flow rate of about 10 sccm to about 20 sccm.

10. The method of claim 5, wherein the supplying the reactant comprises supplying the hydrogen sulfide into the chamber so that the hydrogen sulfide within the chamber has a partial pressure of about 0.05 torr to about 0.15 torr.

11. An apparatus for forming a tungsten sulfide layer by atomic layer deposition, the apparatus comprising:
a chamber;
a precursor supply unit for supplying a precursor comprising tungsten chloride into the chamber, the precursor supply unit comprising a heating device for heating tungsten chloride of a solid state to generate a gaseous tungsten chloride; and
a reactant supply unit for supplying a reactant comprising hydrogen sulfide into the chamber.

12. The apparatus of claim 11, wherein the precursor supply unit further comprises a bubbling gas supply device for supplying an inert gas to introduce the tungsten chloride into the chamber.

13. The apparatus of claim 12, wherein the bubbling gas supply device supplies the inert gas so that the inert gas within the chamber has a flow rate of about 10 sccm to about 20 sccm.

14. The apparatus of claim 11, wherein the precursor supply unit supplies the tungsten chloride into the chamber so that the tungsten chloride within the chamber has a partial pressure of about 0.01 torr to about 0.02 torr.

15. The apparatus of claim 11, wherein the reactant supply unit supplies the hydrogen sulfide into the chamber so that the hydrogen sulfide within the chamber has a partial pressure of about 0.05 torr to about 0.15 torr.
